(19) United States
(12) Patent Application Publication
(10) Pub. No.: US 2026/0068275 A1
(43) Pub. Date: Mar. 5, 2026

(54) SEMICONDUCTOR DEVICE

(71) Applicant: MEDIATEK INC., Hsinchu City (TW)

(72) Inventors: Tzung-Lin LI, Hsinchu City (TW); Yuan-Fu CHUNG, Hsinchu City (TW); Tung-Hsing LEE, Hsinchu City (TW)

(21) Appl. No.: 19/221,956

(22) Filed: May 29, 2025

Related U.S. Application Data
(60) Provisional application No. 63/687,843, filed on Aug. 28, 2024.

(51) Int. Cl. H10D 64/27; H10D 30/65; H10D 62/10; H10D 64/66

(52) U.S. Cl. CPC H10D 64/518; H10D 30/65; H10D 62/102; H10D 62/116; H10D 62/124; H10D 64/669

(57) ABSTRACT

A semiconductor device is provided. The semiconductor device includes a substrate, first and second wells, first to third doped regions and a segmented gate. The first well having a first conductivity type and the second well having a second conductivity type are disposed in the substrate. The first doped region having the first conductivity type and the second doped region having the second conductivity type are disposed in the first well. The third doped region having the second conductivity type is disposed in the second well. The segmented gate is disposed on the first and the second wells. The segmented gate includes a first gate electrode segment of the second conductivity type, a second gate electrode segment of the first conductivity type and a third gate electrode segment of the first conductivity type. The first gate electrode segment is disposed between the second and third gate electrode segments.

### CROSS REFERENCE TO RELATED APPLICATIONS

This application claims the benefit of U.S. Provisional Application No. 63/687,843, filed on Aug. 28, 2024, the entirety of which is incorporated by reference herein.

### BACKGROUND OF THE DISCLOSURE

### Field of the Disclosure

The present disclosure relates to a semiconductor device. In particular, it relates to a high-voltage metal-oxide-semiconductor field-effect transistor (HV MOS FET).

### Description of the Related Art

As demand for high-voltage devices has increased in recent years, there has been an increasing interest in research on high-voltage metal oxide semiconductor (MOS) transistors for use in high-voltage devices. The high-voltage (HV) MOS devices for use under high voltages, which may be, but are not limited to, voltages higher than the voltage supplied to the I/O circuit. MOS devices, such as HVMOS devices, may function as switches, and they are broadly utilized in audio output drivers, CPU power supplies, power management systems, AC/DC converters, LCD or plasma television drivers, automobile electronic components, PC peripheral devices, small DC motor controllers, and other consumer electronic devices.

Although existing semiconductor devices such as MOS devices and methods of forming the same have been adequate for their intended purposes, they have not been entirely satisfactory in all respects. For example, it is difficult to achieve a balance between smaller on-resistance (Rdson) and lower off-capacitance (Coff).

### BRIEF SUMMARY OF THE DISCLOSURE

An embodiment of the present disclosure provides a semiconductor device. The semiconductor device includes a substrate, a first well, a second well, a first doped region, a second doped region, a third doped region, and a segmented gate. The first well having a first conductivity type is disposed in the substrate. The second well having a second conductivity type is disposed in the substrate and surrounded by the first well. The first doped region having the first conductivity type and a second doped region having the second conductivity type are disposed in the first well. The first doped region and the second doped region are separated from each other by a first isolation feature. The third doped region having the second conductivity type is disposed in the second well. The segmented gate is disposed on the first well and the second well. The segmented gate includes a first gate electrode segment of the second conductivity type, a second gate electrode segment of the first conductivity type and a third gate electrode segment of the first conductivity type. The first gate electrode segment is disposed between the second gate electrode segment and the third gate electrode segment.

An embodiment of the present disclosure provides a semiconductor device. The semiconductor device includes a substrate, a first well, a first doped region, a second doped region, a third doped region, and a segmented gate. The first well having a first conductivity type is disposed in the substrate. The first doped region and a second doped region having a second conductivity type are disposed in the first well. The first doped region and the second doped region are separated from each other by a portion of the first well. The segmented gate is disposed on the portion of the first well. The segmented gate includes a first gate electrode segment of the second conductivity type, a second gate electrode segment of the first conductivity type and a third gate electrode segment of the first conductivity type. The first gate electrode segment is disposed between the second gate electrode segment and the third gate electrode segment.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor device in accordance with some embodiments of the disclosure;

FIG. 2 is an enlarged view of FIG. 1 (or FIG. 5), showing a gate electrode of a segmented gate of the semiconductor device in accordance with some embodiments of the disclosure;

FIG. 3 is a schematic cross-sectional view of a semiconductor device in accordance with some embodiments of the disclosure;

FIG. 4 is an enlarged view of FIG. 3 (or FIG. 6), showing a gate electrode of a segmented gate of the semiconductor device in accordance with some embodiments of the disclosure;

FIG. 5 is a schematic cross-sectional view of a semiconductor device in accordance with some embodiments of the disclosure; and

FIG. 6 is a schematic cross-sectional view of a semiconductor device in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. Like numbers refer to like elements throughout. As used herein, the term “and/or” includes any and all combinations of one or more of the associated listed items.

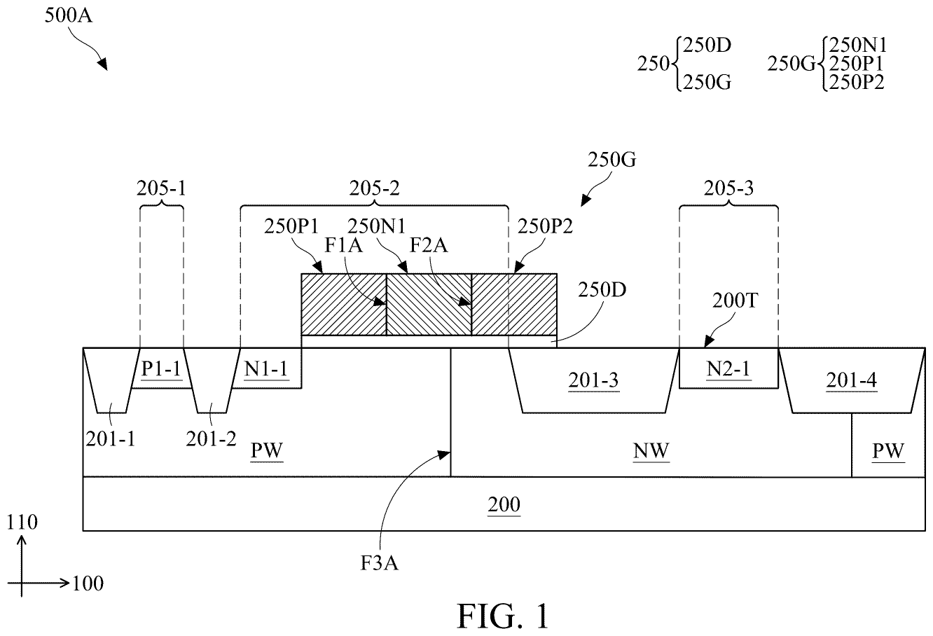

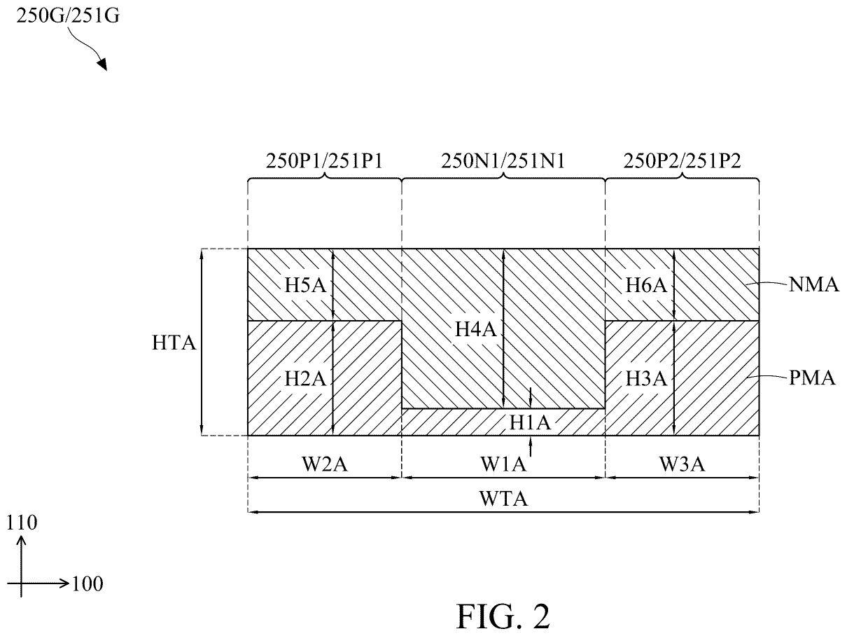

FIG. 1 is a schematic cross-sectional view of a semiconductor device 500A in accordance with some embodiments of the disclosure. FIG. 2 is an enlarged view of FIG. 1, showing a gate electrode 250G of a segmented gate 250 of the semiconductor device 500A in accordance with some embodiments of the disclosure. In some embodiments, the semiconductor device 500A may include a high-voltage metal-oxide-semiconductor field-effect transistor (HV MOS FET), such as a laterally diffused metal-oxide semiconductor (LDMOS) field-effect transistor fabricated by a replacement gate (gate-last) process. As shown in FIG. 1, the semiconductor device 500A may include a substrate 200, a first well PW, a second well NW, a first doped region P1-1, a second doped region N1-1, a third doped region N2-1 and a segmented gate 250.

As shown in FIG. 1, the substrate 200 includes a semiconductor substrate, such as a silicon (Si) substrate or a silicon-germanium (SiGe) substrate. In some embodiments, the substrate 200 includes a bulk semiconductor substrate, a strained semiconductor substrate or a compound semiconductor substrate. In some embodiments, the substrate 200 may be a semiconductor substrate having a conductivity type that is either P-type or N-type. In this embodiment, the substrate 200 is P-type.

The first well PW is disposed in the substrate 200. In some embodiments, the first well PW has a first conductivity type. For example, when the first conductivity type is P-type, the first well PW is a P-type well PW. In addition, the first well PW and the substrate 200 may have the same or opposite conductivity types. In this embodiment, the first well PW and the substrate 200 have the same conductivity type.

The second well NW is disposed in the substrate 200. The second well NW is adjacent to and surrounded by the first well PW. In some embodiments, the second well NW has a second conductivity type that is opposite to the first conductivity type. For example, when the first conductivity type is P-type, the second conductivity type is N-type, the second well NW is an N-type well NW. In some embodiments, the first well PW and the second well NW may have the same depth in direction 110 (the direction substantially vertical to the top surface 200T of the substrate 200).

Each of the first well PW and the second well NW has one or more heavily doped regions formed thereon. For example, a first doped region P1-1 (i.e., a first heavily doped region P1-1) and a second doped region N1-1 (i.e., a second heavily doped region N1-1) are located directly on different portions of the first well PW. In addition, a third doped region N2-1 (i.e., a third heavily doped region N2-1) are located directly on a portion of the second well NW. The first doped region P1-1 and the third doped region N2-1 are located on opposite sides of the second doped region N1-1 in direction 100 (the direction substantially parallel to the top surface 200T of the substrate 200).

In some embodiments, the first doped region P1-1 has the first conductivity type. The second doped region N1-1 and the third doped region N2-1 have the second conductivity type. For example, when the first conductivity type is P-type, the second conductivity type is N-type, the first doped region P1-1 is a P-type doped region P1-1. The second doped region N1-1 and the third doped region N2-1 are N-type doped regions N1-1 and N2-1.

In some embodiments, the conductivity type of the first doped region P1-1 is the same as that of the first well PW. The conductivity type of the second doped region N1-1 and the third doped region N2-1 is opposite to that of the first well PW and the first doped region P1-1. The conductivity type of the second doped region N1-1 and the third doped region N2-1 is the same as that of the second well NW.

In some embodiments, the second doped region N1-1 and the third doped region N2-1 may have the same doping concentration greater than that of the second well NW. In some embodiments, the doping concentration of first doped region P1-1 is greater than that of the first well region PW.

The semiconductor device 500A also includes isolation features 201 (including isolation features 201-1, 201-2, 201-3 and 201-4) such as shallow trench isolation trench isolations (STIs) disposed in the first well PW and the second well NW in the substrate 200. The isolation features 201-1, 201-2, 201-3 and 201-4 may define active regions 205-1, 205-2 and 205-3. As shown in FIG. 1, the first doped region P1-1 and the second doped region N1-1 may be located in different active regions 205-1 and 205-2 defined by the isolation features 201-1. 201-2 and 201-3. The second doped region N1-1 is adjacent to the isolation feature 201-2. Opposite sides of the first doped region P1-1 are adjacent to the isolation features 201-1 and 201-2. In addition, the first doped region P1-1 and the second doped region N1-1 may be separated from each other by the isolation feature 201-2.

As shown in FIG. 1, the second doped region N1-1 and the third doped region N2-1 may be located in the different active regions 205-2 and 205-3 defined by the isolation features 201-2, 201-3 and 201-4. One side of the second doped region N1-1 is adjacent to the isolation feature 201-2, another side of second doped region N1-1 is separated from the isolation feature 201-3 in the direction 100. Opposite sides of the third doped region N2-1 are adjacent to the isolation features 201-3 and 201-4. In addition, the second doped region N1-1 and the third doped region N2-1 may be separated from each other by the isolation feature 201-3.

The segmented gate 250 is disposed on the first well PW and the second well NW. In addition, the segmented gate 250 is located on a portion of the substrate 200 between the second doped region N1-1 and the third doped region N2-1 in the direction 100 (the lateral direction). As shown in FIG. 1, the segmented gate 250 is adjacent to the second doped region N1-1 and separated from the third doped region N2-1 in the direction 100. The segmented gate 250 may extend in the direction 100 to cover a portion of the isolation feature 201-3. In some embodiments, the segmented gate 250, such as a metal gate, includes a gate dielectric layer 250D disposed on the substrate 200 and a gate electrode 250G disposed above the gate dielectric layer 250D.

In some embodiments, the gate dielectric layer 250D includes high-k (the dielectric constant k of greater than silicon dioxide, about 3.9) dielectric material including HfO₂, HfSiO, HfSiON, HfTaO, HfTiO, HfZrO, zirconium oxide, aluminum oxide, hafnium dioxide-alumina (HfO₂—Al₂O₃) alloy, other suitable high-k dielectric materials, and/or combinations thereof.

In some embodiments, the segmented gate 250 may further include an interfacial layer (not shown) formed between the substrate 200 and the gate dielectric layer 250D to improve adhesion between the gate dielectric layer 250D and the gate dielectric layer 250D. In some embodiments, the interfacial layer includes such as SiON or SiO₂.

The gate electrode 250G of the segmented gate 250 includes a first gate electrode segment 250N1, a second gate electrode segment 250P1 and a third gate electrode segment 250P2. In some embodiments, the first gate electrode segment 250N1 is disposed between and adjacent to the second gate electrode segment 250P1 and the third gate electrode segment 250P2. As shown in FIG. 1, the second gate electrode segment 250P1 of the gate electrode 250G of the segmented gate 250 is adjacent to the second doped region N1-1. In addition, the third gate electrode segment 250P2 of the gate electrode 250G of the segmented gate 250 is separated from the third doped region N2-1 in the direction 100 that is substantially parallel the top surface 200T of the substrate 200. In the direction 100, the second gate electrode segment 250P1 and the third gate electrode segment 250P2 are close to edges of the segmented gate 250, and the first gate electrode segment 250N1 is located at the central portion of segmented gate 250.

As shown in FIG. 1, the segmented gate 250 may partially overlap the isolation feature 201-3 in the direction 110 that is substantially vertical to the top surface 200T of the substrate 200. More specifically, the third gate electrode segment 250P2 of the gate electrode 250G of the segmented gate 250 partially overlaps the isolation feature 201-3. The first gate electrode segment 250N1 and the second gate electrode segment 250P1 of the gate electrode 250G of the segmented gate 250 are offset from the isolation feature 201-3 in the direction 100.

In some embodiments, the first gate electrode segment 250N1 has the second conductivity type. The second gate electrode segment 250P1 and the third gate electrode segment 250P2 has the first conductivity type. For example, when the first conductivity type is P-type, the second conductivity type is N-type, the first gate electrode segment 250N1 is an N-type gate electrode segment 250N1, the second gate electrode segment 250P1 is a P-type gate electrode segment 250P1, and the third gate electrode segment 250P2 is a P-type gate electrode segment 250P2.

As shown in FIG. 2, the gate electrode 250G of the segmented gate 250 also includes a first work function metal PMA and a second work function metal NMA disposed on the first work function metal PMA. It is noted that the positions of the first work function metal PMA and the second work function metal NMA may be exchanged (upside-down) and not limited to the disclosed embodiment. For example, as shown in FIG. 1, the first work function metal PMA is located between the gate dielectric layer 250D and the second work function metal NMA in the direction 110. Alternatively, the second work function metal NMA may be disposed between the gate dielectric layer 250D and the first work function metal PMA in the direction 110.

In some embodiments, the first work function metal PMA has the first conductivity type, and the second work function metal NMA has the second conductivity type. For example, when the first conductivity type is P-type, the second conductivity type is N-type, the first work function metal PMA is a P-type work function metal PMA, and the second work function metal NMA is an N-type work function metal NMA. In some embodiments, the first work function metal PMA includes TiN, and the second work function metal NMA includes TiAl.

In some embodiments, each of the first gate electrode segment 250N1, the second gate electrode segment 250P1 and the third gate electrode segment 250P2 may include a portion of the first work function metal PMA and a portion of the second work function metal NMA. As shown in FIG. 1, in the direction 110 (the vertical direction), the first work function metal PMA of the first gate electrode segment 250N1 has a first height H1A, the first work function metal PMA of the second gate electrode segment 250P1 has a second height H2A, the first work function metal PMA of the third gate electrode segment 250P2 has a third height H3A. In some embodiments, the first height H1A is smaller (or lower) than the second height H2A, and the first height H1A is smaller (or lower) than the third height H3A. In some embodiments, the second height H2A may be the same as or different from the third height H3A.

As shown in FIG. 2, the second work function metal NMA of the first gate electrode segment 250N1 has a fourth height H4A, the second work function metal NMA of the second gate electrode segment 250P1 has a fifth height H5A, the second work function metal NMA of the third gate electrode segment 250P2 has a sixth height H6A. In some embodiments, the fourth height H4A is greater (or higher) than the fifth height H5A, and the fourth height H4A is greater (or higher) than the sixth height H6A. In some embodiments, the fifth height H5A may be the same as or different from the sixth height H6A.

In some embodiments, in each of the first gate electrode segment 250N1, the second gate electrode segment 250P1 and the third gate electrode segment 250P2, the sum of the height of first work function metal PMA and the height of the second work function metal NMA may be equal to the total height HTA of the gate electrode 250G of the segmented gate 250. For example, the sum of the first height H1A and the fourth height H4A is equal to the height HTA of the gate electrode 250G of the segmented gate 250. In addition, the sum of the first height H1A and the fourth height H4A is equal to the sum of the second height H2A and the fifth height H5A. Furthermore, the sum of the first height H1A and the fourth height H4A is equal to the sum of the third height H3A and the sixth height H6A. Therefore, the sum of the second height H2A and the fifth height H5A is equal to the height HTA of the segmented gate 250. The sum of the third height H3A and the sixth height H6A is also equal to the height HTA of the gate electrode 250G of the segmented gate 250.

In some embodiments, the sum of widths of the first gate electrode segment 250N1, the second gate electrode segment 250P1 and the third gate electrode segment 250P2 is equal to the total width of the segmented gate 250G. For example, as shown in FIG. 2, the first gate electrode segment 250N1 has a first width WIA, the second gate electrode segment 250P1 has a second width W2A, the third gate electrode segment 250P3 has a third width W3A. In some embodiments, the sum of the first width WIA, the second width W2A and the third width W3A is equal to the width WTA of the gate electrode 250G of the segmented gate 250.

In some embodiments, the first width WIA is greater than the second width W2A, and the first width WIA is also greater than the third width W3A. In some embodiments, the second width W2A may be the same as or different from the third width W3A.

In some embodiments, the first gate electrode segment 250N1 of the gate electrode 250G of the segmented gate 250 may cover portions of the first well PW and the second well NW. Alternatively, the first gate electrode segment 250N1 of the gate electrode 250G of the segmented gate 250 may cover the first well PW without extending to the second well NW.

As shown in FIG. 1, the second gate electrode segment 250P1 of the gate electrode 250G of the segmented gate 250 may cover a portion of the first well PW. For example, the second gate electrode segment 250P1 may cover a portion of the first well PW without extending to the second well NW. In addition, the third gate electrode segment 250P2 of the gate electrode 250G of the segmented gate 250 a portion of a portion of the second well NW. For example, the third gate electrode segment 250P2 may cover a portion of the second well NW without extending to the first well PW.

In the gate electrode 250G of the segmented gate 250, a first interface F1A between the first gate electrode segment 250N1 and the second gate electrode segment 250P1 is located directly on the first well PW. In some embodiments, a second interface F2A between the first gate electrode segment 250N1 and the third gate electrode segment 250P2 is located directly on the first well PW, the second well NW or a third interface F3A between the first well PW and the second well NW.

As shown in FIG. 1, the segmented gate 250, the first well PW, the second well NW, the first doped region P1-1, the second doped region N1-1 and the second doped region N2-1 may collectively form a first type metal-oxide-semiconductor field-effect transistor (MOS FET). The first type metal-oxide-semiconductor field-effect transistor (MOS FET) is formed in the first well PW and the second well NW. In the first type metal-oxide-semiconductor field-effect transistor, the segmented gate 250 may serve as the gate of the first type metal-oxide-semiconductor field-effect transistor. The first doped region P1-1 may serve as a body or bulk region of the first type metal-oxide-semiconductor field-effect transistor. The second doped region N1-1 may serve as a source region of the first type metal-oxide-semiconductor field-effect transistor. The third doped region N2-1 may serve as a drain region of the first type metal-oxide-semiconductor field-effect transistor. In addition, the second well region NW may serve as a drain extension region of the first type metal-oxide-semiconductor field-effect transistor. A portion of the substrate 200 close to the segmented gate 250 and between the second doped region N1-1 and the second well NW may serve as the channel region of the of the first type metal-oxide-semiconductor field-effect transistor. The channel region has the second conductivity type.

In this embodiment, the first conductivity type is P-type, the second conductivity type is N-type, and the first type metal-oxide-semiconductor field-effect transistor (MOS FET) is an N-type metal-oxide-semiconductor field-effect transistor (NMOS FET) in which the conductivity type of the channel region is N-type. The semiconductor device 500A may serve as a lateral diffused N-type metal-oxide-semiconductor field-effect transistor (LD NMOS FET).

Compared with the conventional LD NMOS FET in which the gate electrode only composed of an N-type work function metal, the semiconductor device 500A of N-type conductivity includes a segmented gate (e.g., the segmented gate 250) in which a gate electrode (e.g., the gate electrode 250G) is composed of an N-type work function metal and a P-type work function metal. The segmented gate includes a plurality of gate electrode segments having different conductivity types by tuning the ratio of the height of the N-type work function metal to the P-type work function metal. For example, in the direction 100 (also serve as the channel direction), the conductivity type of the central gate electrode segment (e.g., the first gate electrode segment 250N1) of the segmented gate is kept the same as the channel region, such as N-type, by tuning the ratio of the height of the N-type work function metal to the P-type work function metal of greater than 1 (e.g., the fourth height H4A is greater (or higher) than first height H1A). In addition, the edge gate electrode segments (e.g., the second gate electrode segment 250P1 and the third gate electrode segment 250P2) of the segmented gate located at the source side and the drain side are converted opposite to the channel region, such as P-type, by tuning the ratio of the height of the N-type work function metal to the P-type work function metal of smaller than 1 (e.g., the fourth height H5A is smaller (or lower) than second height H2A, and the sixth height H6A is smaller (or lower) than the third height H3A). The central gate electrode segment (e.g., the first gate electrode segment 250N1) and the edge gate electrode segments (e.g., the second electrode segment 250P1 and the third electrode segment 250P2) may have the same height (i.e., the total height HTA of the gate electrode 250G). Furthermore, the width (e.g., the width W1A) of the central gate electrode segment (e.g., the first gate electrode segment 250N1) is larger than the widths of the edge gate electrode segments (e.g., the second electrode segment 250P1 and the third electrode segment 250P2), so that the conductivity type of the whole gate electrode 250G may be kept the same as the channel region, such as N-type.

In the segmented gate, the central gate electrode segment (e.g., the first gate electrode segment 250N1) located above the channel region may have a lower threshold voltage to reduce on-resistance (Rdson) of the semiconductor device 500A. The edge gate electrode segments (e.g., the second electrode segment 250P1 and the third electrode segment 250P2) located at the source side and the drain side may have a higher threshold voltage to reduce off-capacitance (Coff) and improve the reliability on the drain side of the semiconductor device 500A.

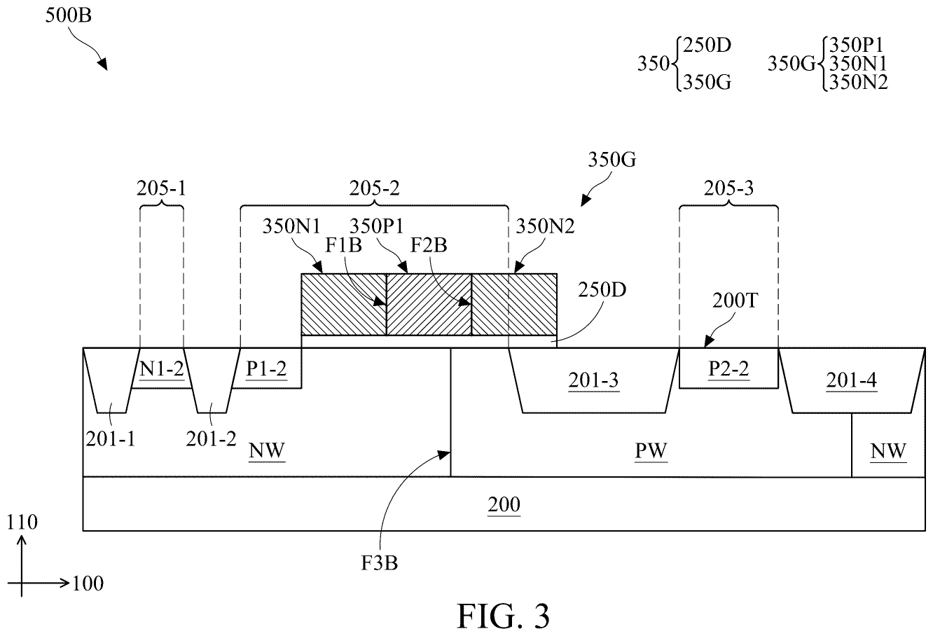

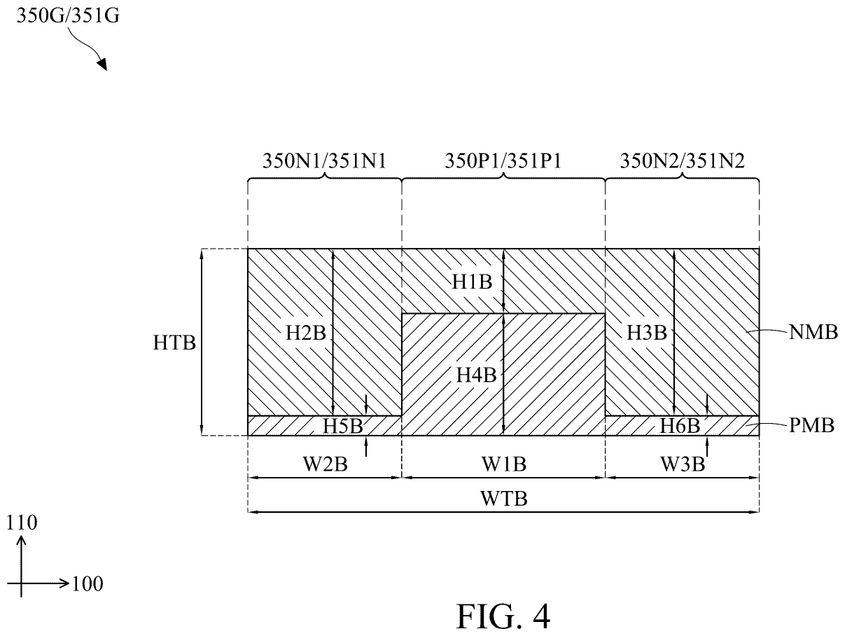

FIG. 3 is a schematic cross-sectional view of a semiconductor device 500B in accordance with some embodiments of the disclosure. FIG. 4 is an enlarged view of FIG. 3, showing a gate electrode 350G of a segmented gate 350 of the semiconductor device 500B in accordance with some embodiments of the disclosure. Elements of the embodiments hereinafter, that are the same or similar as those previously described with reference to FIGS. 1 and 2, are not repeated for brevity. One of the differences between the semiconductor device 500A and the semiconductor device 500B is that the semiconductor device 500B may have the conductivity type opposite to the semiconductor device 500A. For example, in the semiconductor device 500A, the elements having the first conductivity type are P-type elements, and the elements having the second conductivity type are N-type elements. In the semiconductor device 500B, the elements having the first conductivity type are N-type elements, and the elements having the second conductivity type are P-type elements.

As shown in FIG. 3, the semiconductor device 500B may include a substrate 200, a first well NW, a second well PW, a first doped region N1-2, a second doped region P1-2, a third doped region P2-2 and a segmented gate 350.

As shown in FIG. 3, the substrate 200 includes a semiconductor substrate, such as a silicon (Si) substrate or a silicon-germanium (SiGe) substrate. In some embodiments, the substrate 200 includes a bulk semiconductor substrate, a strained semiconductor substrate or a compound semiconductor substrate. In some embodiments, the substrate 200 may be a semiconductor substrate having a conductivity type that is either P-type or N-type. In this embodiment, the substrate 200 is P-type.

The first well NW is disposed in the substrate 200. In some embodiments, the first well NW has a first conductivity type. For example, when the first conductivity type is N-type, the first well NW is a N-type well NW. In addition, the first well NW and the substrate 200 may have the same or opposite conductivity types. In this embodiment, the first well NW and the substrate 200 have the opposite conductivity types.

The second well PW is disposed in the substrate 200. The second well PW is adjacent to and surrounded by the first well NW. In some embodiments, the second well PW has a second conductivity type that is opposite to the first conductivity type. For example, when the first conductivity type is N-type, the second conductivity type is P-type, the second well PW is an N-type well NW. In some embodiments, the first well NW and the second well PW may have the same depth in the direction 110 (the direction substantially vertical to the top surface 200T of the substrate 200).

Each of the first well NW and the second well PW has one or more heavily doped regions formed thereon. For example, a first doped region N1-2 (i.e., a first heavily doped region N1-2) and a second doped region P1-2 (i.e., a second heavily doped region P1-2) are located directly on different portions of the first well NW. In addition, a third doped region P2-2 (i.e., a third heavily doped region P2-2) are located directly on a portion of the second well PW. The first doped region N1-2 and the third doped region P2-2 are located on opposite sides of the second doped region P1-2 in the direction 100 (the direction substantially parallel to the top surface 200T of the substrate 200).

In some embodiments, the first doped region N1-2 has the first conductivity type. The second doped region P1-2 and the third doped region P2-2 have the second conductivity type. For example, when the first conductivity type is N-type, the second conductivity type is P-type, the first doped region N1-2 is a P-type doped region N1-2. The second doped region P1-2 and the third doped region P2-2 are N-type doped regions P1-2 and P2-2.

In some embodiments, the conductivity type of the first doped region N1-2 is the same as that of the first well NW. The conductivity type of the second doped region P1-2 and the third doped region P2-2 is opposite to that of the first well NW and the first doped region N1-2. The conductivity type of the second doped region P1-2 and the third doped region P2-2 is the same as that of the second well PW.

In some embodiments, the second doped region P1-2 and the third doped region P2-2 may have the same doping concentration greater than that of the. In some embodiments, the doping concentration of first doped region N1-2 is greater than that of the first well region PW.

As shown in FIG. 3, the first doped region N1-2 and the second doped region P1-2 may be located in different active regions 205-1 and 205-2 defined by the isolation features 201-1. 201-2 and 201-3. The second doped region P1-2 is adjacent to the isolation feature 201-2. Opposite sides of the first doped region N1-2 are adjacent to the isolation features 201-1 and 201-2. In addition, the first doped region N1-2 and the second doped region P1-2 may be separated from each other by the isolation feature 201-2.

As shown in FIG. 3, the second doped region P1-2 and the third doped region P2-2 may be located in the different active regions 205-2 and 205-3 defined by the isolation features 201-2, 201-3 and 201-4. One side of the second doped region P1-2 is adjacent to the isolation feature 201-2, another side of second doped region P1-2 is separated from the isolation feature 201-3 in the direction 100. Opposite sides of the third doped region P2-2 are adjacent to the isolation features 201-3 and 201-4. In addition, the second doped region P1-2 and the third doped region P2-2 may be separated from each other by the isolation feature 201-3.

The segmented gate 350 is disposed on the first well NW and the second well PW. In addition, the segmented gate 350 is located on a portion of the substrate 200 between the second doped region P1-2 and the third doped region P2-2 in the direction 100 (the lateral direction). As shown in FIG. 3, the segmented gate 350 is adjacent to the second doped region P1-2 and separated from the third doped region P2-2 in the direction 100. The segmented gate 350 may extend in the direction 100 to cover a portion of the isolation feature 201-3. In some embodiments, the segmented gate 350 includes a gate dielectric layer 250D disposed on the substrate 200 and a gate electrode 350G disposed above the gate dielectric layer 250D.

In some embodiments, the segmented gate 350 may further include an interfacial layer (not shown) formed between the substrate 200 and the gate dielectric layer 250D to improve adhesion between the gate dielectric layer 250D and the gate dielectric layer 250D. In some embodiments, the interfacial layer includes such as SiON or SiO₂.

The gate electrode 350G of the segmented gate 350 includes a first gate electrode segment 350P1, a second gate electrode segment 350N1 and a third gate electrode segment 350N2. In some embodiments, the first gate electrode segment 350P1 is disposed between and adjacent to the second gate electrode segment 350N1 and the third gate electrode segment 350N2. As shown in FIG. 3, the second gate electrode segment 350N1 of the gate electrode 350G of the segmented gate 350 is adjacent to the second doped region P1-2. In addition, the third gate electrode segment 350N2 of the gate electrode 350G of the segmented gate 350 is separated from the third doped region P2-2 in the direction 100 that is substantially parallel the top surface 200T of the substrate 200. In the direction 100, the second gate electrode segment 350N1 and the third gate electrode segment 350N2 are close to edges of the segmented gate 350, and the first gate electrode segment 350P1 is located at the central portion of segmented gate 350.

As shown in FIG. 3, the segmented gate 350 may partially overlap the isolation feature 201-3 in the direction 110 that is substantially vertical to the top surface 200T of the substrate 200. More specifically, the third gate electrode segment 350N2 of the gate electrode 350G of the segmented gate 350 partially overlaps the isolation feature 201-3. The first gate electrode segment 350P1 and the second gate electrode segment 350N1 of the gate electrode 350G of the segmented gate 350 are offset from the isolation feature 201-3 in the direction 100.

In some embodiments, the first gate electrode segment 350P1 has the second conductivity type. The second gate electrode segment 350N1 and the third gate electrode segment 350N2 has the first conductivity type. For example, when the first conductivity type is N-type, the second conductivity type is P-type, the first gate electrode segment 350P1 is an N-type gate electrode segment 350P1, the second gate electrode segment 350N1 is a P-type gate electrode segment 350N1, and the third gate electrode segment 350N2 is a P-type gate electrode segment 350N2.

As shown in FIG. 4, the gate electrode 350G of the segmented gate 350 also includes a first work function metal NMB and a second work function metal PMB disposed on the first work function metal NMB (in the direction negative to the direction 110). It is noted that the positions of the first work function metal NMB and the second work function metal PMB may be exchanged (upside-down) and not limited to the disclosed embodiment. For example, as shown in FIG. 3, the second work function metal PMB is located between the gate dielectric layer 250D and the first work function metal NMB in the direction 110. Alternatively, the first work function metal NMB may be disposed between the gate dielectric layer 250D and the second work function metal PMB in the direction 110.

In some embodiments, the first work function metal NMB has the first conductivity type, and the second work function metal PMB has the second conductivity type. For example, when the first conductivity type is N-type, the second conductivity type is P-type, the first work function metal NMB is a P-type work function metal NMB, and the second work function metal PMB is an N-type work function metal PMB. In some embodiments, the first work function metal NMB includes TiN, and the second work function metal PMB includes TiAl.

In some embodiments, each of the first gate electrode segment 350P1, the second gate electrode segment 350N1 and the third gate electrode segment 350N2 may include a portion of the first work function metal NMB and a portion of the second work function metal PMB. As shown in FIG. 4, in the direction 110 (the vertical direction), the first work function metal NMB of the first gate electrode segment 350P1 has a first height H1B, the first work function metal NMB of the second gate electrode segment 350N1 has a second height H2B, the first work function metal NMB of the third gate electrode segment 350N2 has a third height H3B. In some embodiments, the first height H1B is smaller (or lower) than the second height H2B, and the first height H1B is smaller (or lower) than the third height H3B. In some embodiments, the second height H2B may be the same as or different from the third height H3B.

As shown in FIG. 4, the second work function metal PMB of the first gate electrode segment 350P1 has a fourth height H4B, the second work function metal PMB of the second gate electrode segment 350N1 has a fifth height H5B, the second work function metal PMB of the third gate electrode segment 350N2 has a sixth height H6B. In some embodiments, the fourth height H4B is greater (or higher) than the fifth height H5B, and the fourth height H4B is greater (or higher) than the sixth height H6B. In some embodiments, the fifth height H5B may be the same as or different from the sixth height H6B.

In some embodiments, in each of the first gate electrode segment 350P1, the second gate electrode segment 350N1 and the third gate electrode segment 350N2, the sum of the height of the first work function metal NMB and the height of the second work function metal PMB may be equal to the total height HTB of the gate electrode 350G of the segmented gate 350. For example, the sum of the first height H1B and the fourth height H4B is equal to the height HTB of the gate electrode 350G of the segmented gate 350. In addition, the sum of the first height H1B and the fourth height H4B is equal to the sum of the second height H2B and the fifth height H5B. Furthermore, the sum of the first height H1B and the fourth height H4B is equal to the sum of the third height H3B and the sixth height H6B. Therefore, the sum of the second height H2B and the fifth height H5B is equal to the height HTB of the segmented gate 350. The sum of the third height H3B and the sixth height H6B is also equal to the height HTB of the gate electrode 350G of the segmented gate 350.

In some embodiments, the sum of widths of the first gate electrode segment 350P1, the second gate electrode segment 350N1 and the third gate electrode segment 350N2 is equal to the total width of the segmented gate 350G. For example, as shown in FIG. 4, the first gate electrode segment 350P1 has a first width W1B, the second gate electrode segment 350N1 has a second width W2B, the third gate electrode segment 250P3 has a third width W3B. In some embodiments, the sum of the first width W1B, the second width W2B and the third width W3B is equal to the width WTB of the gate electrode 350G of the segmented gate 350.

In some embodiments, the first width W1B is greater than the second width W2B, and the first width W1B is also greater than the third width W3B. In some embodiments, the second width W2B may be the same as or different from the third width W3B.

In some embodiments, the first gate electrode segment 350P1 of the gate electrode 350G of the segmented gate 350 may cover portions of the first well NW and the second well PW. Alternatively, the first gate electrode segment 350P1 of the gate electrode 350G of the segmented gate 350 may cover the first well NW without extending to the second well PW.

As shown in FIG. 3, the second gate electrode segment 350N1 of the gate electrode 350G of the segmented gate 350 may cover a portion of the first well NW. For example, the second gate electrode segment 350N1 may cover a portion of the first well NW without extending to the second well PW. In addition, the third gate electrode segment 350N2 of the gate electrode 350G of the segmented gate 350 a portion of a portion of the second well PW. For example, the third gate electrode segment 350N2 may cover a portion of the second well PW without extending to the first well NW.

In the gate electrode 350G of the segmented gate 350, a first interface F1B between the first gate electrode segment 350P1 and the second gate electrode segment 350N1 is located directly on the first well NW. In some embodiments, a second interface F2B between the first gate electrode segment 350P1 and the third gate electrode segment 350N2 is located directly on the first well NW, the second well PW or a third interface F3B between the first well NW and the second well PW.

As shown in FIG. 3, the segmented gate 350, the first well NW, the second well PW, the first doped region N1-2, the second doped region P1-2 and the second doped region P2-2 may collectively form a second type metal-oxide-semiconductor field-effect transistor (MOS FET). The second type metal-oxide-semiconductor field-effect transistor (MOS FET) is formed in the first well NW and the second well PW. In the second type metal-oxide-semiconductor field-effect transistor, the segmented gate 350 may serve as the gate of the second type metal-oxide-semiconductor field-effect transistor. The first doped region N1-2 may serve as the body or bulk region of the second type metal-oxide-semiconductor field-effect transistor. The second doped region P1-2 may serve as the source region of the second type metal-oxide-semiconductor field-effect transistor. The third doped region P2-2 may serve as the drain region of the second type metal-oxide-semiconductor field-effect transistor. In addition, the second well region NW may serve as a drain extension region of the second type metal-oxide-semiconductor field-effect transistor. A portion of the substrate 200 close to the segmented gate 350 and between the second doped region P1-2 and the second well PW may serve as the channel region of the of the second type metal-oxide-semiconductor field-effect transistor. The channel region has the second conductivity type.

In this embodiment, the first conductivity type is N-type, the second conductivity type is P-type, and the second type metal-oxide-semiconductor field-effect transistor (MOS FET) is a P-type metal-oxide-semiconductor field-effect transistor (PMOS FET) in which the conductivity type of the channel region is P-type. The semiconductor device 500B may serve as a lateral diffused P-type metal-oxide-semiconductor field-effect transistor (LD PMOS FET).

Compared with the conventional LD PMOS FET in which the gate electrode only composed of a P-type work function metal, the semiconductor device 500B of P-type conductivity includes a segmented gate (e.g., the segmented gate 350) in which a gate electrode (e.g., the gate electrode 350G) is composed of an N-type work function metal and a P-type work function metal. The segmented gate includes a plurality of gate electrode segments having different conductivity types by tuning the ratio of the height of the N-type work function metal to the P-type work function metal. For example, in the direction 100 (also serve as the channel direction), the conductivity type of the central gate electrode segment (e.g., the first gate electrode segment 350P1) of the segmented gate is kept the same as the channel region, such as P-type, by tuning the ratio of the height of the P-type work function metal to the N-type work function metal of greater than 1 (e.g., the fourth height H4B is greater (or higher) than first height H1B). In addition, the edge gate electrode segments (e.g., the second gate electrode segment 350N1 and the third gate electrode segment 350N2) of the segmented gate located at the source side and the drain side are converted opposite to the channel region, such as N-type, by tuning the ratio of the height of the P-type work function metal to the N-type work function metal of smaller than 1 (e.g., the fourth height H5B is smaller (or lower) than second height H2B, and the sixth height H6B is smaller (or lower) than the third height H3B). The central gate electrode segment (e.g., the first gate electrode segment 350P1) and the edge gate electrode segments (e.g., the second electrode segment 350N1 and the third electrode segment 350N2) may have the same height (i.e., the total height HTB of the gate electrode 350G). Furthermore, the width (e.g., the width W1B) of the central gate electrode segment (e.g., the first gate electrode segment 350P1) is larger than the widths of the edge gate electrode segments (e.g., the second electrode segment 350N1 and the third electrode segment 350N2), so that the conductivity type of the whole gate electrode 350G may be kept the same as the channel region, such as P-type.

In the segmented gate, the central gate electrode segment (e.g., the first gate electrode segment 350P1) located above the channel region may have a lower threshold voltage to reduce on-resistance (Rdson) of the semiconductor device 500B. The edge gate electrode segments (e.g., the second electrode segment 350N1 and the third electrode segment 350N2) located at the source side and the drain side may have a higher threshold voltage to reduce off-capacitance (Coff) and improve the reliability on the drain side of the semiconductor device 500B.

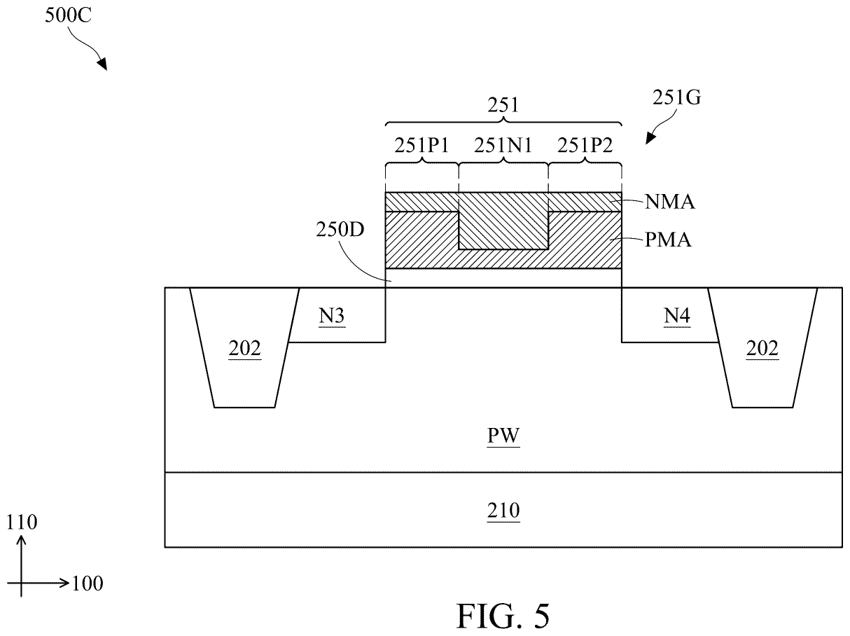

FIG. 5 is a schematic cross-sectional view of a semiconductor device 500C in accordance with some embodiments of the disclosure. FIG. 2 is also an enlarged view of FIG. 5, showing a gate electrode 251G of a segmented gate 251 of the semiconductor device 500C in accordance with some embodiments of the disclosure. Elements of the embodiments hereinafter, that are the same as or similar to those previously described with reference to FIGS. 1 and 2, are not repeated for brevity. In some embodiments, the segmented gate 251 of the semiconductor device 500C is the same as or similar to the segmented gate 250 of the semiconductor device 500A (as shown in FIGS. 1 and 2). The differences between the semiconductor device 500A and the semiconductor device 500C include at least the substrate, with a substrate 210 in the semiconductor device 500C being different from the substrate 200 in the semiconductor device 500A.

As shown in FIG. 5, the semiconductor device 500C may include a substrate 210, a first well PW, a first doped region N3, a second doped region N4 and the segmented gate 251. The substrate 210 includes a semiconductor substrate, such as a silicon (Si) substrate or a silicon-germanium (SiGe) substrate. In some embodiments, the substrate 210 includes a bulk semiconductor substrate, a strained semiconductor substrate or a compound semiconductor substrate. In some embodiments, the substrate 210 may be a semiconductor substrate having a conductivity type that is either P-type or N-type. In this embodiment, the substrate 210 is P-type. The first well PW is disposed in the substrate 210. In some embodiments, the first well PW has a first conductivity type. For example, when the first conductivity type is P-type, the first well PW is a P-type well PW. In addition, the first well PW and the substrate 210 may have the same or opposite conductivity types. In this embodiment, the first well PW and the substrate 210 have the same conductivity type. In some embodiments, only the first well PW is disposed in the substrate 210 and no second well (NW) is present in the substrate 210.

The first doped region N3 (i.e., a first heavily doped region N3) and a second doped region N4 (i.e., a second heavily doped region N4) are located directly on different portions of the first well PW. In some embodiments, the first doped region N3 is adjacent to a first sidewall of the segmented gate 251, and the second doped region N4 is adjacent to a second sidewall of the segmented gate 251. In addition, the first sidewall and the second sidewall are the two opposite sidewalls of the segmented gate 251. In some embodiments, the first doped region N3 and the second doped region N4 have the second conductivity type. For example, when the first conductivity type is P-type, the second conductivity type is N-type, the first doped region N3 and the second doped region N4 are N-type doped regions N3 and N4, respectively. In some embodiments, the first doped region N3 and the second doped region N4 may have the same doping concentration.

The semiconductor device 500C also includes isolation features 202 such as shallow trench isolation trench isolations (STIs) disposed in the first well PW in the substrate 210. The isolation features 202 may define an active region of the semiconductor device 500C and may be used to isolation the first doped region N3 and the second doped region N4 from other regions.

The segmented gate 251 is directly disposed on the first well PW. A portion of the first well PW close to the segmented gate 251 and between the first doped region N3 and the second doped region N4 may serve as the channel region of the of the first type metal-oxide-semiconductor field-effect transistor. The channel region has the second conductivity type. In some embodiment, the segmented gate 251 is directly disposed on the portion of the first well PW or directly disposed on the channel region. The first doped region N3 and the second doped region N4 are separate by the portion of the first well PW or the channel region.

In this embodiment, the first conductivity type is P-type, the second conductivity type is N-type, and the first type metal-oxide-semiconductor field-effect transistor (MOS FET) is an N-type metal-oxide-semiconductor field-effect transistor (NMOS FET) in which the conductivity type of the channel region is N-type. The semiconductor device 500C may serve as an N-type metal-oxide-semiconductor field-effect transistor (NMOS FET).

In some embodiment, the segmented gate 251 of the semiconductor device 500C (as shown in FIGS. 5 and 2) is same as the segmented gate 250 of the semiconductor device 500A (as shown in FIGS. 1 and 2). Compared with the conventional NMOS FET in which the gate electrode only composed of an N-type work function metal, the semiconductor device 500C of N-type conductivity includes a segmented gate (e.g., the segmented gate 251) in which a gate electrode (e.g., the gate electrode 251G) is composed of an N-type work function metal (e.g., a second work function metal NMA) and a P-type work function metal (e.g., a first work function metal PMA). The segmented gate includes a plurality of gate electrode segments having different conductivity types by tuning the ratio of the height of the N-type work function metal to the P-type work function metal. For example, in the direction 100 (also serve as the channel direction), the conductivity type of the central gate electrode segment (e.g., the first gate electrode segment 251N1) of the segmented gate is kept the same as the channel region, such as N-type, by tuning the ratio of the height of the N-type work function metal to the P-type work function metal of greater than 1 (e.g., the fourth height H4A is greater (or higher) than first height H1A). In addition, the edge gate electrode segments (e.g., the second gate electrode segment 251P1 and the third gate electrode segment 251P2) of the segmented gate located at the source side and the drain side are converted opposite to the channel region, such as P-type, by tuning the ratio of the height of the N-type work function metal to the P-type work function metal of smaller than 1 (e.g., the fourth height H5A is smaller (or lower) than second height H2A, and the sixth height H6A is smaller (or lower) than the third height H3A). The central gate electrode segment (e.g., the first gate electrode segment 251N1) and the edge gate electrode segments (e.g., the second electrode segment 251P1 and the third electrode segment 251P2) may have the same height (i.e., the total height HTA of the gate electrode 251G). Furthermore, the width (e.g., the width W1A) of the central gate electrode segment (e.g., the first gate electrode segment 251N1) is larger than the widths of the edge gate electrode segments (e.g., the second electrode segment 251P1 and the third electrode segment 251P2), so that the conductivity type of the whole gate electrode 251G may be kept the same as the channel region, such as N-type. In the segmented gate, the central gate electrode segment (e.g., the first gate electrode segment 251N1) located above the channel region may have a lower threshold voltage to reduce on-resistance (Rdson) of the semiconductor device 500C. The edge gate electrode segments (e.g., the second electrode segment 251P1 and the third electrode segment 251P2) located at the source side and the drain side may have a higher threshold voltage to reduce off-capacitance (Coff) and improve the reliability on the drain side of the semiconductor device 500C.

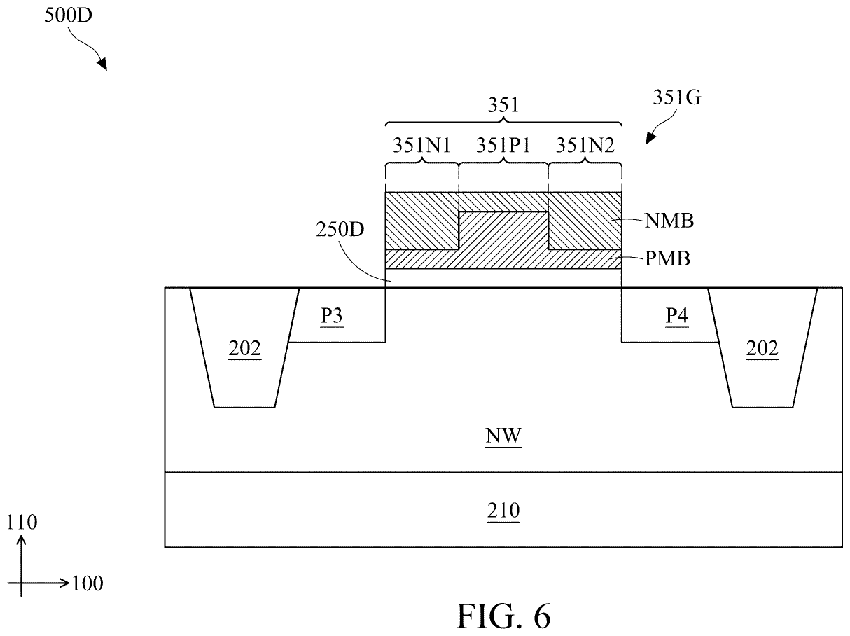

FIG. 6 is a schematic cross-sectional view of a semiconductor device 500D in accordance with some embodiments of the disclosure. FIG. 4 is also an enlarged view of FIG. 6, showing a gate electrode 351G of a segmented gate 351 of the semiconductor device 500D in accordance with some embodiments of the disclosure. Elements of the embodiments hereinafter, that are the same or similar as those previously described with reference to FIGS. 3 and 4, are not repeated for brevity. In some embodiments, the segmented gate 351 of the semiconductor device 500D (as shown in FIGS. 6 and 4) is the same as or similar to the segmented gate 350 of the semiconductor device 500B (as shown in FIGS. 3 and 4). The differences between the semiconductor device 500B and the semiconductor device 500D include at least the substrate, with a substrate 210 in the semiconductor device 500D being different from the substrate 200 in the semiconductor device 500B.

As shown in FIG. 6, the semiconductor device 500D may include a substrate 210, a first well NW, a first doped region P3, a second doped region P4 and the segmented gate 351. The substrate 210 includes a semiconductor substrate, such as a silicon (Si) substrate or a silicon-germanium (SiGe) substrate. In some embodiments, the substrate 210 includes a bulk semiconductor substrate, a strained semiconductor substrate or a compound semiconductor substrate. In some embodiments, the substrate 210 may be a semiconductor substrate having a conductivity type that is either P-type or N-type. In this embodiment, the substrate 210 is P-type. The first well NW is disposed in the substrate 210. In some embodiments, the first well NW has a first conductivity type. For example, when the first conductivity type is N-type, the first well NW is an N-type well NW. In addition, the first well NW and the substrate 210 may have the same or opposite conductivity types. In this embodiment, the first well NW and the substrate 210 have the opposite conductivity types. In some embodiments, only the first well NW is disposed in the substrate 210 and no second well (PW) is present in the substrate 210.

The first doped region P3 (i.e., a first heavily doped region P3) and a second doped region P4 (i.e., a second heavily doped region P4) are located directly on different portions of the first well NW. In some embodiments, the first doped region P3 is adjacent to a first sidewall of the segmented gate 351, and the second doped region P4 is adjacent to a second sidewall of the segmented gate 351. In addition, the first sidewall and the second sidewall are the two opposite sidewalls of the segmented gate 351. In some embodiments, the first doped region P3 and the second doped region P4 have a second conductivity type. For example, when the first conductivity type is N-type, the second conductivity type is P-type, the first doped region P3 and the second doped region P4 are P-type doped regions P3 and P4, respectively. In some embodiments, the first doped region P3 and the second doped region P4 may have the same doping concentration.

The semiconductor device 500D also includes isolation features 202 such as shallow trench isolation trench isolations (STIs) disposed in the first well NW in the substrate 210. The isolation features 202 may define an active region of the semiconductor device 500D and may be used to isolation the first doped region P3 and the second doped region P4 from other regions.

The segmented gate 351 is directly disposed on the first well NW. A portion of the first well NW close to the segmented gate 351 and between the first doped region P3 and the second doped region P4 may serve as the channel region of the of the second type metal-oxide-semiconductor field-effect transistor. The channel region has the second conductivity type. In some embodiment, the segmented gate 351 is directly disposed on the portion of the first well NW or directly disposed on the channel region. The first doped region P3 and the second doped region P4 are separate by the portion of the first well NW or the channel region.

In this embodiment, the first conductivity type is N-type, the second conductivity type is P-type, and the second type metal-oxide-semiconductor field-effect transistor (MOS FET) is a P-type metal-oxide-semiconductor field-effect transistor (PMOS FET) in which the conductivity type of the channel region is P-type. The semiconductor device 500D may serve as a P-type metal-oxide-semiconductor field-effect transistor (PMOS FET).

In some embodiment, the segmented gate 351 of the semiconductor device 500D (as shown in FIGS. 6 and 4) is same as the segmented gate 350 of the semiconductor device 500B (as shown in FIGS. 3 and 4). Compared with the conventional PMOS FET in which the gate electrode only composed of a P-type work function metal, the semiconductor device 500D of P-type conductivity includes a segmented gate (e.g., the segmented gate 351) in which a gate electrode (e.g., the gate electrode 351G) is composed of an N-type work function metal (e.g., a first work function metal NMB) and a P-type work function metal (e.g., a second work function metal PMB). The segmented gate includes a plurality of gate electrode segments having different conductivity types by tuning the ratio of the height of the P-type work function metal to the N-type work function metal. For example, in the direction 100 (also serve as the channel direction), the conductivity type of the central gate electrode segment (e.g., the first gate electrode segment 351P1) of the segmented gate is kept the same as the channel region, such as P-type, by tuning the ratio of the height of the P-type work function metal to the N-type work function metal of greater than 1 (e.g., the fourth height H4B is greater (or higher) than first height H1B). In addition, the edge gate electrode segments (e.g., the second gate electrode segment 351N1 and the third gate electrode segment 351N2) of the segmented gate located at the source side and the drain side are converted opposite to the channel region, such as P-type, by tuning the ratio of the height of the P-type work function metal to the N-type work function metal of smaller than 1 (e.g., the fourth height H5B is smaller (or lower) than second height H2B, and the sixth height H6B is smaller (or lower) than the third height H3B). The central gate electrode segment (e.g., the first gate electrode segment 351P1) and the edge gate electrode segments (e.g., the second electrode segment 351N1 and the third electrode segment 351N2) may have the same height (i.e., the total height HTB of the gate electrode 351G). Furthermore, the width (e.g., the width W1B) of the central gate electrode segment (e.g., the first gate electrode segment 351P1) is larger than the widths of the edge gate electrode segments (e.g., the second electrode segment 351N1 and the third electrode segment 351N2), so that the conductivity type of the whole gate electrode 351G may be kept the same as the channel region, such as P-type. In the segmented gate, the central gate electrode segment (e.g., the first gate electrode segment 351P1) located above the channel region may have a lower threshold voltage to reduce on-resistance (Rdson) of the semiconductor device 500D. The edge gate electrode segments (e.g., the second electrode segment 351N1 and the third electrode segment 351N2) located at the source side and the drain side may have a higher threshold voltage to reduce off-capacitance (Coff) and improve the reliability on the drain side of the semiconductor device 500D.

Embodiments provide a semiconductor device. The semiconductor device includes a substrate, a first well, a second well, a first doped region, a second doped region, a third doped region, and a segmented gate. The first well having the first conductivity type is disposed in the substrate. The second well having a second conductivity type is disposed in the substrate and surrounded by the first well. The first doped region having the first conductivity type and the second doped region having the second conductivity type are disposed in the first well. The first doped region and the second doped region are separated by a first isolation feature. The third doped region having the second conductivity type is disposed in the second well. The segmented gate is disposed on the first well and the second well. The segmented gate includes a first gate electrode segment of the second conductivity type, a second gate electrode segment of the first conductivity type and a third gate electrode segment of the first conductivity type. The first gate electrode segment is disposed between the second gate electrode segment and the third gate electrode segment.

In some embodiments, the first doped region serves as the body or bulk region of the semiconductor device.

In some embodiments, the second doped region serves as the source region of the semiconductor device.

In some embodiments, the third doped region serves as the drain region of the semiconductor device.

In some embodiments, the segmented gate includes a first work function metal of the first conductivity type and a second work function metal of the second conductivity type disposed on the first work function metal.

In some embodiments, when the first conductivity type is p-type and the second conductivity type is n-type, the first work function metal includes TiN, and the second work function metal includes TiAl.

In some embodiments, when the first conductivity type is n-type and the second conductivity type is p-type, the first work function metal includes TiAl, and the second work function metal includes TiN.

In some embodiments, the first work function metal of the first gate electrode segment has a first height, the first work function metal of the second gate electrode segment has a second height, the first work function metal of the third gate electrode segment has a third height, the first height is smaller (or lower) than the second height, and the first height is smaller (or lower) than the third height.

In some embodiments, the second work function metal of the first gate electrode segment has a fourth height, the second work function metal of the second gate electrode segment has a fifth height, the second work function metal of the third gate electrode segment has a sixth height, the fourth height is greater (or higher) than the fifth height, and the fourth height is greater (or higher) than the sixth height.

In some embodiments, the sum of the first height and the fourth height is equal to a height of a gate electrode of the segmented gate.

In some embodiments, the sum of the first height and the fourth height is equal to the sum of the second height and the fifth height, and the sum of the first height and the fourth height is equal to the sum of the third height and the sixth height.

In some embodiments, the first gate electrode segment has a first width, the second gate electrode segment has a second width, the third gate electrode segment has a third width, the sum of the first width, the second width and the third width is equal to the width of a gate electrode of the segmented gate.

In some embodiments, the first width is greater than the second width, and the first width is also greater than the third width.

In some embodiments, the first gate electrode segment of the segmented gate covers the first well and the second well.

In some embodiments, the second gate electrode segment of the segmented gate covers the first well, and the third gate electrode segment of the segmented gate covers the second well.

In some embodiments, a first interface between the first gate electrode segment of the segmented gate and the second gate electrode segment of the segmented gate is located directly on the first well.

In some embodiments, a second interface between the first gate electrode segment of the segmented gate and the third gate electrode segment of the segmented gate is located directly on the first well, the second well or a third interface between the first well and the second well.

In some embodiments, the second gate electrode segment of the segmented gate is adjacent to the second doped region, and the third gate electrode segment of the segmented gate is separated from the third doped region in a direction that is substantially parallel the top surface of the substrate.

In some embodiments, the semiconductor device further includes a second isolation feature disposed in the second well and adjacent to the third doped region. The segmented gate partially overlaps the second isolation feature.

In some embodiments, the first gate electrode segment and the second gate electrode segment of the segmented gate are offset from the second isolation feature.

Embodiments provide a semiconductor device. The semiconductor device includes a substrate, a first well, a first doped region, a second doped region, a third doped region, and a segmented gate. The first well having a first conductivity type is disposed in the substrate. The first doped region and a second doped region having a second conductivity type are disposed in the first well. The first doped region and the second doped region are separated from each other by a portion of the first well. The segmented gate is disposed on the portion of the first well. The segmented gate includes a first gate electrode segment of the second conductivity type, a second gate electrode segment of the first conductivity type and a third gate electrode segment of the first conductivity type. The first gate electrode segment is disposed between the second gate electrode segment and the third gate electrode segment.

In some embodiments, the portion of the first well serve as a channel region of the semiconductor device.

In some embodiments, the segmented gate comprises a first work function metal of the first conductivity type and a second work function metal of the second conductivity type disposed on the first work function metal, wherein the first work function metal of the first gate electrode segment has a first height, the first work function metal of the second gate electrode segment has a second height, the first work function metal of the third gate electrode segment has a third height, the first height is smaller (or lower) than the second height, and the first height is smaller (or lower) than the third height.

In some embodiments, the first gate electrode segment has a first width, the second gate electrode segment has a second width, the third gate electrode segment has a third width), wherein the first width is greater than the second width, and the first width is also greater than the third width.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a first well having a first conductivity type disposed in the substrate;
a second well having a second conductivity type disposed in the substrate and surrounded by the first well;
a first doped region having the first conductivity type and a second doped region having the second conductivity type disposed in the first well, wherein the first doped region and the second doped region are separated from each other by a first isolation feature;
a third doped region having the second conductivity type disposed in the second well; and
a segmented gate disposed on the first well and the second well, wherein the segmented gate comprises a first gate electrode segment of the second conductivity type, a second gate electrode segment of the first conductivity type and a third gate electrode segment of the first conductivity type, and wherein the first gate electrode segment is disposed between the second gate electrode segment and the third gate electrode segment.

2. The semiconductor device as claimed in claim 1, wherein the first doped region serves as a body or a bulk region of the semiconductor device.

3. The semiconductor device as claimed in claim 1, wherein the second doped region serves as a source region of the semiconductor device.

4. The semiconductor device as claimed in claim 1, wherein the third doped region serves as a drain region of the semiconductor device.

5. The semiconductor device as claimed in claim 1, wherein the segmented gate comprises a first work function metal of the first conductivity type and a second work function metal of the second conductivity type disposed on the first work function metal.

6. The semiconductor device as claimed in claim 5, wherein when the first conductivity type is p-type and the second conductivity type is n-type, the first work function metal comprises TiN, and the second work function metal comprises TiAl, or when the first conductivity type is n-type and the second conductivity type is p-type, the first work function metal comprises TiAl, and the second work function metal comprises TiN.

7. The semiconductor device as claimed in claim 5, wherein the first work function metal of the first gate electrode segment has a first height, the first work function metal of the second gate electrode segment has a second height, the first work function metal of the third gate electrode segment has a third height, the first height is lower than the second height, and the first height is lower than the third height.

8. The semiconductor device as claimed in claim 7, wherein the second work function metal of the first gate electrode segment has a fourth height, the second work function metal of the second gate electrode segment has a fifth height, the second work function metal of the third gate electrode segment has a sixth height, the fourth height is higher than the fifth height, and the fourth height is higher than the sixth height.

9. The semiconductor device as claimed in claim 8, wherein the sum of the first height and the fourth height is equal to the sum of the second height and the fifth height, and the sum of the first height and the fourth height is equal to a sum of the third height and the sixth height.

10. The semiconductor device as claimed in claim 1, wherein the first gate electrode segment has a first width, the second gate electrode segment has a second width, the third gate electrode segment has a third width, wherein the first width is greater than the second width, and the first width is also greater than the third width.

11. The semiconductor device as claimed in claim 1, wherein the first gate electrode segment of the segmented gate covers the first well and the second well.

12. The semiconductor device as claimed in claim 11, wherein the second gate electrode segment of the segmented gate covers the first well, and the third gate electrode segment of the segmented gate covers the second well.

13. The semiconductor device as claimed in claim 12, wherein a first interface between the first gate electrode segment of the segmented gate and the second gate electrode segment of the segmented gate is located directly on the first well.

14. The semiconductor device as claimed in claim 12, wherein a second interface between the first gate electrode segment of the segmented gate and the third gate electrode segment of the segmented gate is located directly on the first well, the second well or a third interface between the first well and the second well.

15. The semiconductor device as claimed in claim 1, wherein the second gate electrode segment of the segmented gate is adjacent to the second doped region, and the third gate electrode segment of the segmented gate is separated from the third doped region in a direction that is substantially parallel a top surface of the substrate.

16. The semiconductor device as claimed in claim 10, further comprising:
a second isolation feature disposed in the second well and adjacent to the third doped region, wherein the segmented gate partially overlaps the second isolation feature.

17. A semiconductor device, comprising:
a substrate;
a first well having a first conductivity type disposed in the substrate;
a first doped region and a second doped region having a second conductivity type disposed in the first well, wherein the first doped region and the second doped region are separated from each other by a portion of the first well; and
a segmented gate disposed on the portion of the first well, wherein the segmented gate comprises a first gate electrode segment of the second conductivity type, a second gate electrode segment of the first conductivity type and a third gate electrode segment of the first conductivity type, and wherein the first gate electrode segment is disposed between the second gate electrode segment and the third gate electrode segment.

18. The semiconductor device as claimed in claim 17, wherein the portion of the first well serve as a channel region of the semiconductor device.

19. The semiconductor device as claimed in claim 17, wherein the segmented gate comprises a first work function metal of the first conductivity type and a second work function metal of the second conductivity type disposed on the first work function metal, wherein the first work function metal of the first gate electrode segment has a first height, the first work function metal of the second gate electrode segment has a second height, the first work function metal of the third gate electrode segment has a third height, the first height is lower than the second height, and the first height is lower than the third height.

20. The semiconductor device as claimed in claim 17, wherein the first gate electrode segment has a first width, the second gate electrode segment has a second width, the third gate electrode segment has a third width, wherein the first width is greater than the second width, and the first width is also greater than the third width.
